(19) United States
(12) Patent Application Publication
(10) Pub. No.: US 2024/0072087 A1
(43) Pub. Date: Feb. 29, 2024

(54) IMAGE SENSING DEVICE AND METHOD FOR MANUFACTURING THE SAME

(71) Applicant: SK hynix Inc., Icheon-si (KR)

(72) Inventor: Won Jin KIM, Icheon-si (KR)

(21) Appl. No.: 18/359,693

(22) Filed: Jul. 26, 2023

(30) Foreign Application Priority Data
Aug. 26, 2022 (KR) 10-2022-0107844

(51) Int. Cl. H01L 27/146

(52) U.S. Cl. CPC H01L 27/14623; H01L 27/14621; H01L 27/14645; H01L 27/14685

(57) ABSTRACT

An image sensing device includes a plurality of image sensing pixels configured to respond to light incident through first color filters and generate image signals corresponding to a target object to be captured, at least one phase detection pixel configured to respond to light incident through a second color filter and generate a phase signal for calculating a phase difference between images generated by the image signals, a first grid structure disposed between the adjacent first color filter and the second color filter and including a light absorption layer, and a second grid structure disposed between adjacent first color filters and structured to be free from the light absorption layer.

### CROSS-REFERENCE TO RELATED APPLICATION

This patent document claims the priority and benefits of Korean patent application No. 10-2022-0107844, filed on Aug. 26, 2022, which is incorporated by reference in its entirety as part of the disclosure of this patent document.

### TECHNICAL FIELD

The technology and implementations disclosed in this patent document generally relate to an image sensing device and a method for manufacturing the same.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

In an attempt to achieve the demanded resolution and high-speed operation, image sensor manufacturers are developing multi-layer image sensors that include upper layers stacked on lower layers and through silicon via (TSV) structures that electrically connect circuits of the upper and lower layers to each other.

### SUMMARY

Various embodiments of the disclosed technology relate to an image sensing device capable of suppressing light incident upon a phase detection pixel from penetrating adjacent image sensing pixels even in a highly integrated pixel array.

In accordance with an embodiment of the disclosed technology, an image sensing device may include a plurality of image sensing pixels configured to respond to light incident through first color filters and generate image signals corresponding to a target object to be captured, at least one phase detection pixel configured to respond to light incident through a second color filter and generate a phase signal for calculating a phase difference between images generated by the image signals, a first grid structure disposed between the adjacent first color filters and the second color filter and including a light absorption layer, and a second grid structure disposed between adjacent first color filters and structured to be free from the light absorption layer.

In accordance with another embodiment of the disclosed technology, an image sensing device may include a plurality of image sensing pixels configured to generate image signals corresponding to a target object to be captured, one or more phase detection pixel disposed between the image sensing pixels, an air layer disposed both between color filters of the image sensing pixels and between color filters of the image sensing pixels and a color filter of the phase detection pixel, and a light absorption layer disposed between color filters of the image sensing pixels and a color filter of the phase detection pixel.

In accordance with another embodiment of the disclosed technology, a method for manufacturing an image sensing device may include forming a first pattern including a first light absorption layer pattern and a sacrificial layer pattern in a first region and forming a second pattern including the sacrificial layer pattern in a second region, wherein the second pattern is formed without having the first light absorption layer pattern and the first region and the second region are located on a substrate including photoelectric conversion elements and device isolation structures such that the first pattern and the second pattern are arranged to overlap the device isolation structures, forming a capping layer pattern covering the first pattern and the second pattern, and removing the sacrificial layer pattern from the first pattern and the second pattern.

The forming the first pattern and the second pattern includes forming a second light absorption layer pattern having a larger width than the first light absorption layer pattern, forming a sacrificial layer over the substrate and the second light absorption layer pattern and etching the sacrificial layer and the second light absorption layer pattern.

The forming the second light absorption layer pattern includes forming a black photoresist layer pattern having a first thickness on the substrate and performing a photoresist descum (PR Descum) process on the black photoresist layer pattern to reduce a thickness of the black photoresist layer pattern to a second thickness thinner than the first thickness.

The sacrificial layer pattern includes a carbon-containing Spin On Carbon (SOC) layer.

The removing the sacrificial layer pattern includes performing a plasma process using gas containing at least one of oxygen, nitrogen, or hydrogen on the first pattern and the second pattern covered with the capping layer pattern.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a partial planar structure of a pixel array based on some implementations of the disclosed technology.

FIG. 3 is a cross-sectional view illustrating an example of a pixel array taken along the line X-X′ shown in FIG. 2 based on some implementations of the disclosed technology.

FIGS. 4A to 4H are cross-sectional views illustrating examples of a method for forming the structure of FIG. 3 based on some implementations of the disclosed technology.

FIG. 5 is a schematic diagram illustrating an example of a partial planar structure of a pixel array based on some other implementations of the disclosed technology.

### DETAILED DESCRIPTION

This patent document provides implementations and examples of an image sensing device and a method for manufacturing the same that may be used in specific ways to substantially address one or more technical or engineering issues and mitigate limitations or disadvantages encountered in some other image sensing devices. Some implementations of the disclosed technology suggest designs of an image sensing device capable of suppressing light incident upon a phase detection pixel from penetrating adjacent image sensing pixels even in a highly integrated pixel array. The disclosed technology provides various implementations of an image sensing device which can suppress light incident upon a phase detection pixel from penetrating adjacent image sensing pixels even in a highly integrated pixel array.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

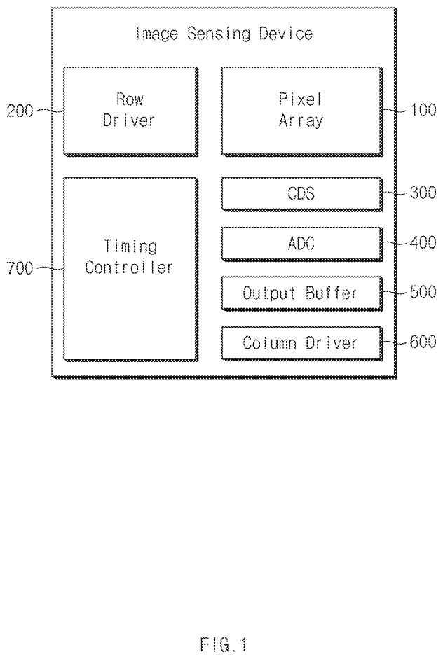

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light, and a phase detection pixel that is structured to generate second electrical signals for calculating a phase difference between the images.

The pixel array 100 may include a plurality of unit pixels arranged in rows and columns. In one example, the plurality of unit pixels can be arranged in a two dimensional (2D) pixel array including rows and columns. In another example, the plurality of unit pixels can be arranged in a three dimensional (3D) pixel array. The plurality of unit pixels may convert an optical signal into an electrical signal on a unit pixel basis or a pixel group basis, where unit pixels in a pixel group share at least certain internal circuitry. The plurality of unit pixels may include a plurality of imaging pixels and a plurality of phase detection pixels. Each of the image sensing pixels may generate an image signal inform of an electrical signal corresponding to an image of a target object to be captured.

The pixel array 100 may receive driving signals (for example, a row selection signal, a reset signal, a transmission (or transfer) signal, etc.) from the row driver 200. Upon receiving the driving signal, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 50 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

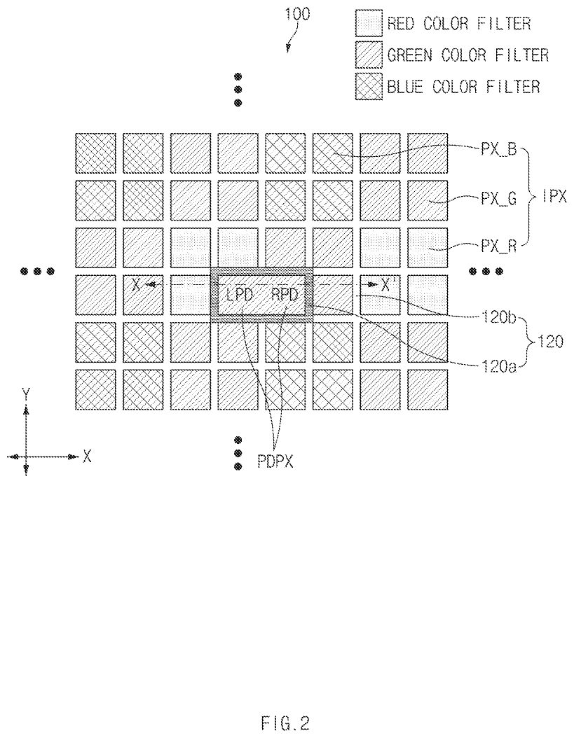

FIG. 2 is a schematic diagram illustrating an example of a partial planar structure of the pixel array 100 shown in FIG. 1 based on some implementations of the disclosed technology.

Referring to FIG. 2, the pixel array 100 may include a plurality of unit pixels consecutively arranged in row and column directions. The plurality of unit pixels may include a plurality of image sensing pixels (IPX), and a plurality of phase detection pixel pairs (PDPX).

Although only one pair of phase detection pixels LPD and RPD is illustrated in FIG. 2 for convenience of description, the pixel array 100 may include a plurality of phase detection pixel pairs (PDPX). For example, the plurality of phase detection pixel pairs (PDPX) may be continuously formed at regular intervals in a horizontal direction and a vertical direction throughout the pixel array 100.

The plurality of image sensing pixels (IPX) may detect and respond to incident light to generate image signals corresponding to an image of a target object from which the incident light is reflected scattered. The plurality of image sensing pixels (IPX) may include a red pixel (PX_R) for selectively detecting red light in the incident light to generate an image signal corresponding to the detected red light, a green pixel (PX_G) for selectively detecting green light in the incident light to generate an image signal corresponding to the detected green light, and a blue pixel (PX_B) for selectively detecting blue light in the incident light to generate an image signal corresponding to the detected blue light.

Each of the image sensing pixels (IPX) may include the unit pixels arranged in an (N×N) array (where, ‘N’ is a natural number of 2 or greater) and include color filters over the image sensing pixels to filter colors of the incident light to be detected by the IPX, respectively. In some implementations, a red pixel (PX_R) includes a photoelectric conversion element covered by a red color filter which selectively allows the red light to pass through while blocking light of other colors from passing through the red color filter, a green pixel (PX_G) includes a photoelectric conversion element covered by a green color filter which selectively allows the green light to pass through while blocking light of other colors from passing through the green color filter, and a blue pixel (PX_B) includes a photoelectric conversion element covered by a blue color filter which selectively allows the blue light to pass through while blocking light of other colors from passing through the blue color filter. In some implementations, the image sensing pixels (IPX) may include red sub-pixel blocks, each of which has a structure in which four red pixels (PX_R) are arranged in a (2×2) array, green sub-pixel blocks, each of which has a structure in which four green pixels (PX_G) are arranged in a (2×2) array, and blue sub-pixel blocks, each of which has a structure in which four blue color pixels (PX_B) are arranged in a (2×2) array. The pixel array 100 may include a quad structure in which four red sub-pixel blocks, four green sub-pixel blocks, and four blue sub-pixel blocks are arranged in a Bayer pattern.

The phase detection pixel pairs (PDPX) may be disposed between the image sensing pixels (IPX) to generate phase signals for calculating a phase difference between images formed by capturing an image of a target object. The plurality of phase detection pixel pairs (PDPX) may include two phase detection pixels adjacent to each other in a horizontal direction (X-axis direction) or in a vertical direction (Y-axis direction). For example, each of the phase detection pixel pairs (PDPX) may include a first phase detection pixel LPD and a second phase detection pixel RPD that are disposed adjacent to each other in the horizontal direction, as shown in FIG. 2.

Although the first and second phase detection pixels LPD and RPD included in the phase detection pixel pair (PDPX) shown in FIG. 2 are disposed adjacent to each other in a horizontal direction for convenience of description, the first and second phase detection pixels LPD and RPD can also be disposed adjacent to each other in a vertical direction. In other implementations, each of the phase detection pixel pairs (PDPX) may include four phase detection pixels (arranged in a (2×2) array) adjacent to each other in horizontal and vertical directions so as to detect both a horizontal phase difference and a vertical phase difference.

The first and second phase detection pixels LPD and RPD included in each of the phase detection pixel pairs (PDPX) may include color filters that are configured to allow light of the same color to pass therethrough. For example, as shown in FIG. 2, the first and second phase detection pixels LPD and RPD may include green color filters. Although FIG. 2 illustrates the color filter corresponding to the same color is configured for each unit pixel (for each image sensing pixel, or for each phase detection pixel), other implementations are also possible. For example, only one color filter corresponding to the same color can be configured for multiple unit pixels disposed adjacent to each other.

In the pixel array 100, a grid structure 120 for preventing crosstalk between adjacent color filters may be formed between color filters of the unit pixels. In some implementations, the grid structure 120 may include a grid structure 120a disposed between the color filters in a boundary region between the image sensing pixel (IPX) and the phase detection pixel LPD or RPD, and a grid structure 120b disposed between the color filters in a boundary region between the image sensing pixels (IPX). In some implementations, the grid structure 120a may be different in structure from the grid structure 120b. For example, the grid structure 120a disposed between each of the color filters of the adjacent image sensing pixels (IPX) and each of the color filters of the phase detection pixels LPD and RPD may include a stacked structure in which a black photoresist layer and an air layer are stacked. In some implementations, the grid structure 120b disposed between the color filters of the adjacent image sensing pixels (IPX) may include an air layer without a black photoresist layer. A grid structure may not be disposed between the phase detection pixels LPD and RPD in the phase detection pixel pair (PDPX).

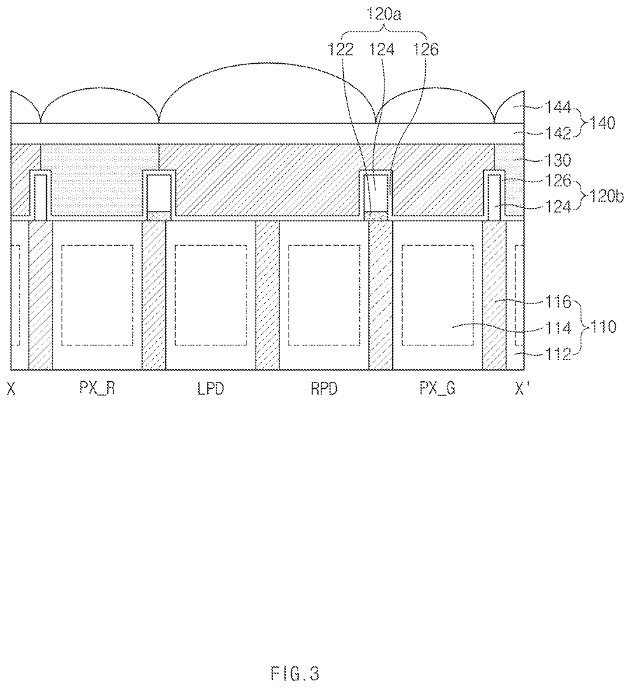

FIG. 3 is a cross-sectional view illustrating an example of the pixel array 100 taken along the line X-X′ shown in FIG. 2 based on some implementations of the disclosed technology.

Referring to FIG. 3, the pixel array 100 may include a substrate layer 110, a grid structure 120, a color filter layer 130, and a lens layer 140.

The substrate layer 110 may include a substrate 112, a plurality of photoelectric conversion regions 114, and a plurality of device isolation structures 116. The substrate layer 110 may include a first surface and a second surface facing away from or opposite to the first surface. In this case, the first surface may refer to a light receiving surface upon which light is incident from the outside, and the color filter layer 130 and the lens layer 140 may be formed over the first surface. Pixel transistors (not shown) for reading out photocharges generated by the photoelectric conversion region 114 of the corresponding unit pixel may be formed in each unit pixel region of the second surface.

The substrate 112 may include a semiconductor substrate including a monocrystalline silicon material. The substrate 112 may include P-type impurities.

The photoelectric conversion regions 114 may be formed in the semiconductor substrate 112 and each photoelectric conversion region 114 can be disposed in a corresponding unit pixel. The photoelectric conversion regions 114 may perform photoelectric conversion of incident light (e.g., visible light) filtered by the color filter layer 130 to generate photocharges that carry images captured by the incident light. Each of the photoelectric conversion regions 114 may include N-type impurities.

Each of the device isolation structures 116 may be formed between photoelectric conversion regions 114 of the adjacent unit pixels within the substrate 112 to isolate the photoelectric conversion regions 114 from each other. The device isolation structure 116 may include a trench structure such as a Back Deep Trench Isolation (BDTI) structure or a Front Deep Trench Isolation (FDTI) structure. The device isolation structure 116 may include a structure in which a Deep Trench Isolation (DTI) structure and a Shallow Trench Isolation (STI) structure are stacked. Alternatively, the device isolation structure 116 may include a junction isolation structure formed by implanting high-density impurities (e.g., P-type impurities) into the substrate 112.

The grid structure 120 may be disposed between the color filters of the adjacent unit pixels to prevent crosstalk between the adjacent color filters. The grid structure 120 may be formed over the first surface of the substrate layer 110. The grid structure 120 may include the first grid structure 120a and the second grid structure 120b.

The first grid structure 120a may be disposed between one of the color filters of the image sensing pixels PX_R, PX_G, and PX_B and one of the color filters of the phase detection pixels LPD and RPD. The first grid structure 120a may include a black photoresist layer 122, an air layer 124, and a capping layer 126. The second grid structure 120b may be disposed between color filters of adjacent image sensing pixels PX_R, PX_G, and PX_B. The second grid structure 120b may include an air layer 124 and a capping layer 126. The first grid structure 120a may be larger in width than the second grid structure 120b.

In the pixel array, the light incident on the phase detection pixels LPD and RPD can transfer to the image sensing pixels PX_R, PX_G, and PX_B, which causes the undesired crosstalk. In some implementations, the black photoresist layer 122 may absorb light penetrating from the phase detection pixels LPD and RPD to the image sensing pixels PX_R, PX_G, and PX_B, thereby preventing light introduced into the phase detection pixels LPD and RPD from transferring to the image sensing pixels PX_R, PX_G, and PX_B. The black photoresist layer 122 may include a photoresist dyed with a black dye, and may be formed to a thickness of about 1500 Å. The capping layer 126 may define a region in which the air layer 124 is formed, and may include a nitride layer. The capping layer 126 may be formed to extend below the color filter layer 130 while covering the air layer 124 or the black photoresist layer 122 and the air layer 124. In the capping layer 126, a region formed below the color filter layer 130 may be used as a portion of an anti-reflection layer.

When the pixel size (pitch) is reduced to 0.6 μm or less, it is very difficult (practically impossible) to use metal for a light absorption layer of the grid structure. At a pixel size (pitch) of 0.6 μm or less, it is almost impossible to use metal for a portion of the grid structure. However, when the grid structure is formed of only the air layer without the metal, light introduced into the phase detection pixels LPD and RPD may relatively easily penetrate into the adjacent image sensing pixels PX_R, PX_G, and PX_B, which causes to lower the light sensitivity of the phase detection pixels LPD and RPD. Thus, in order to address this issue, a material layer for blocking crosstalk of light is needed between each of the color filters of the phase detection pixels LPD and RPD and each of the color filters of the image sensing pixels PX_R, PX_G, and PX_B. Since it is almost impossible to form a metal layer in a grid structure when the pixel size is smaller than 0.6 μm or less, the disclosed technology suggests selectively forming the black photoresist layer for the grid structures. According to this implementation of the disclosed technology, the black photoresist layer 122 may be selectively formed only between each of the color filters of the phase detection pixels LPD and RPD and each of the color filters of the image sensing pixels PX_R, PX_G, and PX_B, thereby preventing light introduced into the phase detection pixels LPD and RPD from penetrating the adjacent image sensing pixels PX_R, PX_G, and PX_B. The black photoresist layer 122 may be omitted in the grid structures formed between the color filters of the image sensing pixels PX_R, PX_G, and PX_B. The color filter layer 130 may include color filters that filter visible light from among incident light received through the lens layer 140 and transmit the filtered light to the corresponding photoelectric conversion regions 114. The color filter layer 130 may include a plurality of red color filters, a plurality of green color filters, and a plurality of blue color filters. Each red color filter may transmit red visible light having a first wavelength band. Each green color filter may transmit green visible light having a second wavelength band shorter than the first wavelength band. Each blue color filter may transmit blue visible light having a third wavelength band shorter than the second wavelength band. In the same-color unit pixels adjacent to each other, one color filter may be formed across the entirety of the corresponding unit pixels.

The lens layer 140 may include an over-coating layer 142 and a plurality of microlenses 144. The over-coating layer 142 may be formed over the color filter layer 130. The over-coating layer 142 may operate as a planarization layer to compensate for (or remove) a step difference caused by the color filter layer 130. The microlenses 144 may be formed over the over-coating layer 142. Each of the microlenses 144 may be formed in a hemispherical shape, and may be formed per unit pixel. The microlenses 144 may converge incident light, and may transmit the converged light to the corresponding color filters. One microlens may be formed over each of the image sensing pixels PX_R, PX_G, and PX_B. One microlens may be formed to cover all of the color filters of the two phase detection pixels LPD and RPD. The over-coating layer 142 and the microlenses 144 may be formed of the same materials.

Referring to FIG. 3, the grid structure 120 may be disposed to be aligned with the device isolation structures 116, and the color filters and the microlenses 144 may be disposed to be aligned with the photoelectric conversion regions 114 of the corresponding unit pixels. In some implementations, in order to improve shading variations, the grid structures 120, the color filters layer 130, and the microlenses 144 may be shifted by a predetermined distance corresponding to a chief ray angle (CRA) according to where the image sensing pixels PX_R, PX_G, and PX_B or the phase detection pixels LPD and RPD are placed in the pixel array 100.

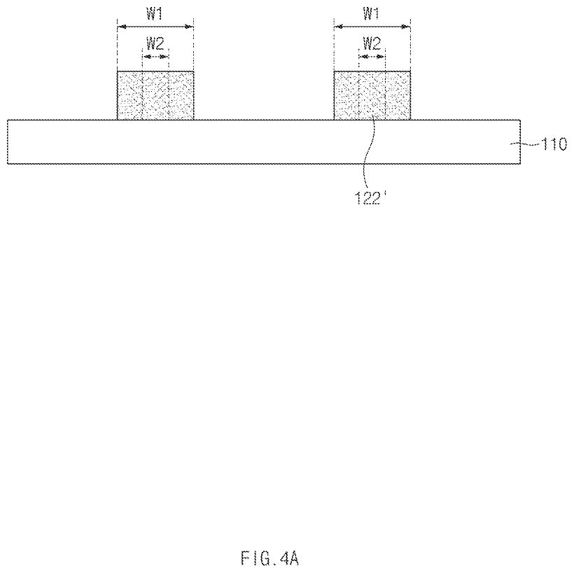

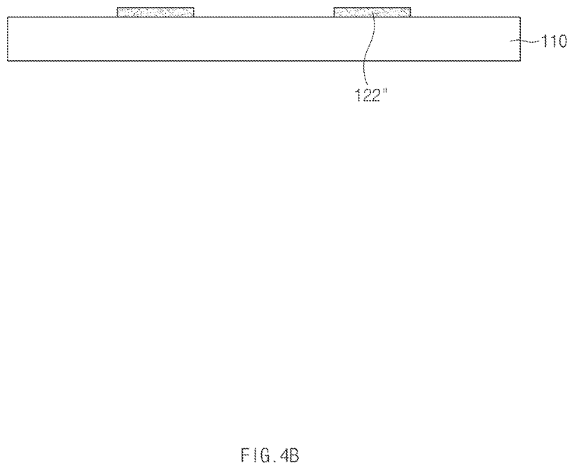

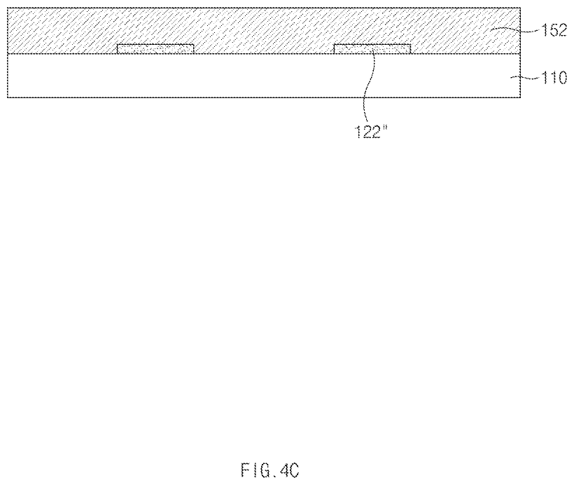

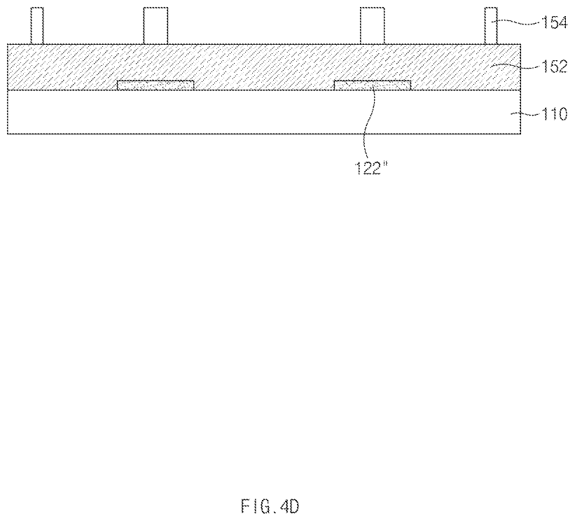

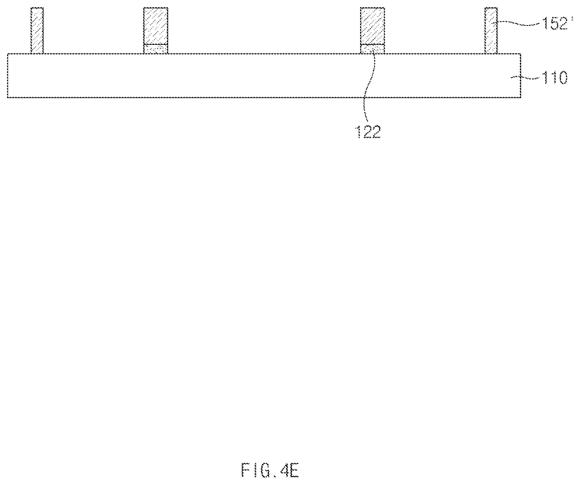

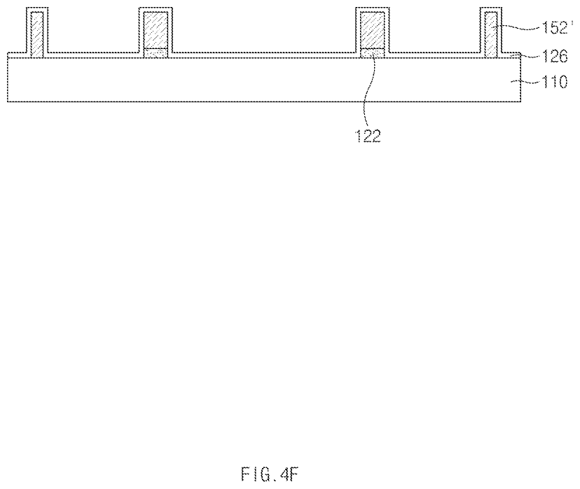

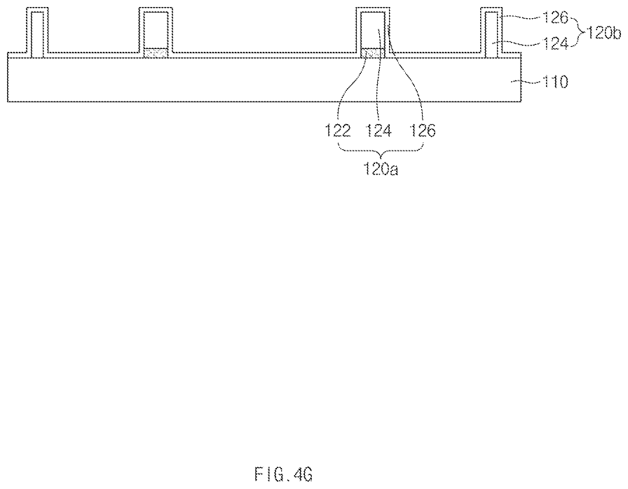

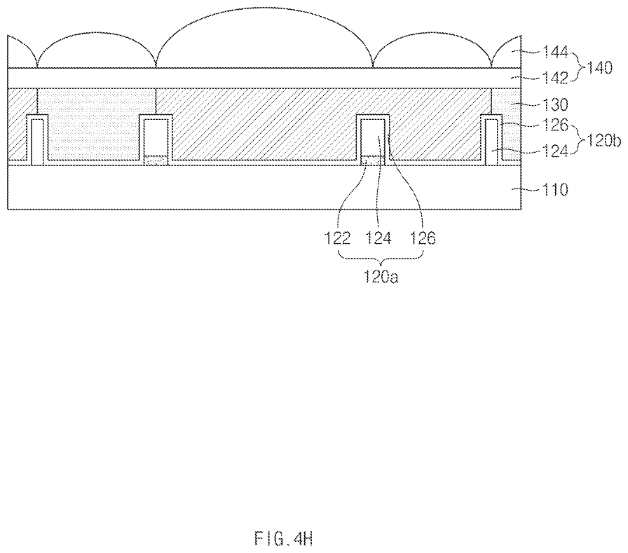

FIGS. 4A to 4H are cross-sectional views illustrating examples of a method for forming the structure of FIG. 3 based on some implementations of the disclosed technology. Since some implementations of the image sensing device provide grid structures that have different structures depending on the locations of the gird structures, the image sensing device will hereinafter be described with reference to a method for forming the grid structures.

Referring to FIG. 4A, a black photoresist layer pattern 122′ may be formed over the substrate layer 110 that includes the photoelectric conversion elements and the device isolation structures 116.

For example, after a black photoresist material is formed to a thickness of about 4000 Å on the substrate layer 110, an exposure and development process is performed on the black photoresist material, so that the black photoresist layer pattern 122′ may be formed in a region where the black photoresist layer 122 is to be formed. In this case, the black photoresist layer pattern 122′ may be formed to be thicker than the black photoresist layer 122 to be actually formed. In addition, a width W1 of the black photoresist layer pattern 122′ may be formed to be larger than a width W2 of the black photoresist layer 122. For example, the black photoresist layer pattern 122′ may be formed to extend sufficiently to both sides while covering the region where the black photoresist layer 122 is to be formed.

Referring to FIG. 4B, a thickness of the black photoresist layer pattern 122′ may be reduced as much as a thickness of the black photoresist layer 122.

For example, a photoresist descum (PR Descum) process using oxygen (O₂) may be performed on the black photoresist layer pattern 122′, resulting in formation of a black photoresist layer pattern 122″ with a thickness reduced to about 1500 Å.

Referring to FIG. 4C, a sacrificial layer 152 may be formed entirely on the substrate layer 110 to cover the black photoresist layer pattern 122″.

In this case, the sacrificial layer 152 may include a carbon-containing spin on carbon (SOC) layer. The sacrificial layer 152 may be formed to a thickness corresponding to the height of the air layer 124 to be formed.

Referring to FIG. 4D, a mask pattern 154 defining a region in which the air layer 124 is to be formed may be formed over the sacrificial layer 152. The mask pattern may include a photoresist pattern.

Referring to FIG. 4E, the sacrificial layer 152 and the black photoresist layer pattern 122″ may be etched using the mask pattern 154 as an etch mask, resulting in formation of a sacrificial layer pattern 152′ and a black photoresist layer 122.

For example, a structure in which the black photoresist layer 122 and a sacrificial layer pattern 152′ are stacked may be formed in a region where the grid structure 120a is to be formed, and a sacrificial layer pattern 152′ may be formed in a region where the grid structure 120b is to be formed without the black photoresist layer 122.

Referring to FIG. 4F, a capping layer 126 may be formed over the substrate layer 110 to cover the black photoresist layer 122 and the sacrificial layer pattern 152′.

The capping layer 126 may include an oxide film, for example, a ULTO (Ultra Low Temperature Oxide) film. In this case, the capping layer 126 may be formed to a predetermined thickness through which molecules formed by combining gas to be used in a subsequent plasma process with carbon of the sacrificial layer pattern 152′ can be easily discharged outside of the capping layer 126. For example, the capping layer 126 may be formed to a thickness of 300 Å or less.

Referring to FIG. 4G, the plasma process may be carried out upon the resultant structure of FIG. 4F, such that the sacrificial layer pattern 152′ may be removed and the air layer 124 may be formed at the position from which the sacrificial layer pattern 152′ is removed. In some implementations, the plasma process may be carried out using gas (e.g., O₂, N₂, H₂, CO, CO₂, or CH₄) including at least one of oxygen, nitrogen, or hydrogen.

For example, if the O₂ plasma process is carried out upon the resultant structure of FIG. 4F, oxygen radicals (O*) may flow into the sacrificial layer pattern 152′ through the capping layer 126, and the oxygen radicals (O*) included in the sacrificial layer pattern 152′ may be combined with carbons of the sacrificial layer pattern 152′, resulting in generation of CO or CO₂. The generated CO or CO₂ may be discharged outside through the capping layer 126. As a result, the sacrificial layer pattern 152′ can be removed, and the air layer 124 may be formed at the position where the sacrificial layer pattern 152′ is removed.

Referring to FIG. 4H, the color filter layer 130 may be formed over the capping layer 126 to fill a space between the grid structures 120a and 120b. Subsequently, an over-coating layer 142 and the microlenses 144 may be sequentially formed over the color filter layer 130.

The method for forming the color filter layer 130, the over-coating layer 142, and the microlenses 144 may be the same as that of the related art.

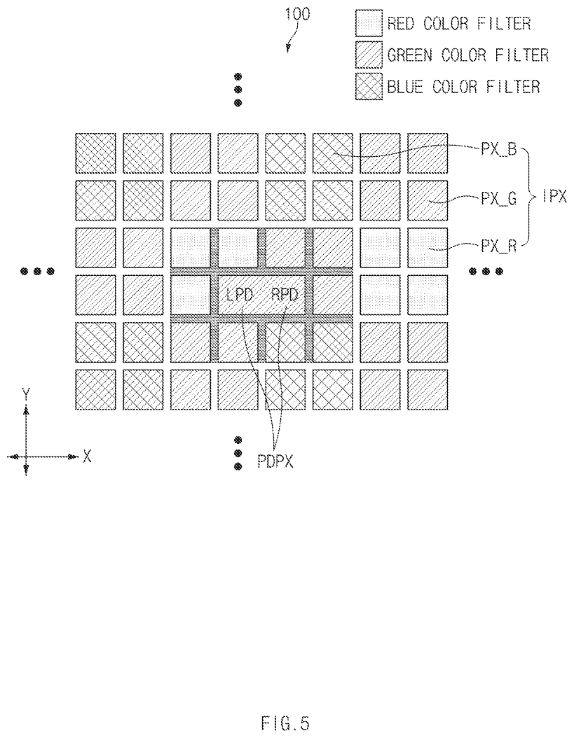

FIG. 5 is a schematic diagram illustrating an example of a partial planar structure of the pixel array 100 based on some other implementations of the disclosed technology.

Referring to FIG. 5, the black photoresist layer 122 in the grid structure may be formed to extend to the image sensing pixels (IPX) adjacent to the phase detection pixel pair (PDPX) while surrounding the phase detection pixel pair (PDPX).

Whereas the black photoresist layer 122 shown in the embodiment of FIG. 2 is formed in a rectangular ring shape surrounding only the phase detection pixel pair (PDPX), the black photoresist layer 122 in the present embodiment may be formed to extend not only to a region between each of the color filters of the adjacent image sensing pixel (IPX) and each of the color filters of the phase detection pixel pair (PDPX), but also to a region between the color filters of some image sensing pixels (IPX) adjacent to the phase detection pixel pair (PDPX) from among the image sensing pixels (IPX).

As described above, the black photoresist layer 122 may be formed to extend to the image sensing pixels (IPX) adjacent to the phase detection pixel pair (PDPX), so that light incident upon the phase detection pixel pair (PDPX) can be more effectively prevented from crosstalk with the image sensing pixels (IPX).

As is apparent from the above description, the image sensing device based on some implementations of the disclosed technology can suppress light incident upon a phase detection pixel from penetrating the adjacent image sensing pixels even in a highly integrated pixel array.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a plurality of image sensing pixels configured to respond to light incident through first color filters and generate image signals corresponding to a target object to be captured;
at least one phase detection pixel configured to respond to light incident through a second color filter and generate a phase signal for calculating a phase difference between images generated by the image signals;
a first grid structure disposed between the first color filters and the second color filter, and including a light absorption layer; and
a second grid structure disposed between adjacent first color filters, and structured to be free from the light absorption layer.

2. The image sensing device according to claim 1, wherein:
the light absorption layer includes a black photoresist layer.

3. The image sensing device according to claim 1, wherein:
the first grid structure includes a black photoresist layer on a first surface of the first grid structure, the black photoresist layer spaced apart from a second surface of the first grid structure to form an air layer disposed over the black photoresist layer and the black photoresist layer and the air layer forming a stacked structure.

4. The image sensing device according to claim 3, wherein:
the first grid structure further includes a capping layer formed to cover the stacked structure.

5. The image sensing device according to claim 4, wherein:
the capping layer is formed to extend to be below the first color filter and the second color filter.

6. The image sensing device according to claim 1, wherein:
the second grid structure includes a capping layer spaced apart from a first surface of the second grid structure to form an air layer on the first surface, the capping layer covering the air layer.

7. The image sensing device according to claim 6, wherein:
the capping layer is formed to extend to be below the first color filters.

8. The image sensing device according to claim 1, wherein:
the first grid structure is formed in a ring shape surrounding the second color filter.

9. The image sensing device according to claim 1, wherein:
the first grid structure surrounds the second color filter, and extends to a region between color filters adjacent to the second color filter from among the first color filters.

10. The image sensing device according to claim 1, wherein the at least one phase detection pixel includes a plurality of phase detection pixels arranged adjacent to each other.

11. The image sensing device according to claim 10, wherein:
the first grid structure surrounds the second color filter, and is not disposed between the plurality of phase detection pixels.

12. The image sensing device according to claim 10, wherein:
the second color filter is a single green color filter formed across and covering all of the plurality of phase detection pixels.

13. An image sensing device comprising:
a plurality of image sensing pixels configured to generate image signals corresponding to a target object to be captured;
one or more phase detection pixel disposed between the image sensing pixels;
an air layer disposed both between color filters of the image sensing pixels and between color filters of the image sensing pixels and a color filter of the phase detection pixel; and
a light absorption layer disposed between color filters of the image sensing pixels and a color filter of the phase detection pixel.

14. The image sensing device according to claim 13, wherein:
the light absorption layer includes a photoresist dyed with a black dye.

15. The image sensing device according to claim 13, wherein:
the light absorption layer is formed in a ring shape surrounding the color filters of the phase detection pixels.

16. The image sensing device according to claim 13, wherein:
the light absorption layer surrounds the color filters of the phase detection pixel, and extends to a region between color filters of image sensing pixels adjacent to the phase detection pixels.

17. The image sensing device according to claim 13, further comprising:
a capping layer formed to cover:
the air layer disposed in a boundary region of the image sensing pixels, and
a stacked structure of the air layer disposed in the boundary region between the phase detection pixel and the image sensing pixels and the light absorption layer.
